(19) United States
(12) Patent Application Publication
(10) Pub. No.: US 2008/0105650 A1
(43) Pub. Date: May 8, 2008

(54) PLASMA PROCESSING DEVICE AND PLASMA PROCESSING METHOD

(76) Inventors: Hideo SUGAI, Nagoya-shi (JP); Tetsuya Ide, Yokohama-shi (JP); Atsushi Sasaki, Yokohama-shi (JP); Kazufumi Azuma, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/969,500

(22) Filed: Jan. 4, 2008

Related U.S. Application Data
(63) Continuation of application No. PCT/JP2006/313123, filed on Jun. 30, 2006.

(30) Foreign Application Priority Data
Jul. 5, 2005 (JP) 2005-196555

(51) Int. Cl. B44C 1/22; C23F 1/00; H05H 1/24; C23C 16/00

(52) U.S. Cl. 216/69; 156/345.41; 118/723 MW; 427/569

(57) ABSTRACT

A plasma processing device reduces the pressure inside a vacuum waveguide which propagates microwave to a vacuum of a high degree, thereby preventing abnormal discharge in the vacuum waveguide and around a slot plate, and reduces the difference in pressure between the processing chamber and the vacuum waveguide, thereby lowering the stress applied on the slot plate and a dielectric member for generating surface plasma, thus carrying out high-quality plasma processing.

### CROSS REFERENCE TO RELATED APPLICATIONS

This is a Continuation Application of PCT Application No. PCT/JP2006/313123, filed Jun. 30, 2006, which was published under PCT Article 21(2) in Japanese.

This application is based upon and claims the benefit of priority from prior Japanese Patent Application No. 2005-196555, filed Jul. 5, 2005, the entire contents of which are incorporated herein by reference.

### BACKGROUND OF THE INVENTION

1. Field of the Invention

The present invention relates to a plasma processing device equipped with a waveguide which propagates electromagnetic waves (microwaves), and a processing method which uses plasma.

2. Description of the Related Art

In general, the process for manufacturing semiconductor devices, liquid crystal display apparatus, etc., includes plasma processing in a step of depositing an oxide film or a conductor film, a surface reforming step such as annealing process, or an etching step of forming a pattern or the like. In order to carry out the plasma processing, a high-frequency plasma processing apparatus including parallel flat-shaped electrodes, an electron cyclotron resonance device and the like are used. Recently, in accordance with the improvement of the device performance, there has been a demand for the establishment of a large area processing technique which can handle substrates to be processed in the display apparatus, with a scale of about 0.5 square meter to about several square meter, in addition to the introduction of a new nanoscale thin film processing technique.

The ordinary type of parallel plate plasma processing apparatus is able to generate large-area relatively easily by increasing the area of the electrode plates opposing to each other, but at the same time, it entails a problem of high electron temperature since the process atmosphere has a high gas pressure and a low plasma density. Further, in the ECR, it is necessary to generate a direct current magnetic field for plasma excitation, and therefore it is difficult to generate large-area plasma from the view point of formation of magnetic field. Moreover, the ordinary type of apparatus entails such a drawback that plasma is easily made ununiform under the influence of the generated magnetic field.

As a solution to the above-discussed drawbacks of an increase in area of substrate to be processed, uniformity of plasma, an increased electron temperature, there has been recently proposed a processing device for generating plasma of a high density and a low electron temperature by using microwave discharge of a non-magnetic field, that is, a processing device which uses the so-called surface wave plasma.

The processing devices which use surface wave plasma, which have been proposed so far, has such a structure that in the plasma generation source, microwave is input to the processing chamber through a dielectric window using a waveguide under atmospheric pressure. The problem in the increased area by the technique using the surface wave plasma is created by the structure in which the inside of the waveguide is at atmospheric pressure, whereas the inside of the processing chamber is reduced to a vacuum state. In other words, a dynamic stress is created due to the pressure difference between both sides of the dielectric window, and the stress increases as the area of the dielectric window is increased, thus increasing the risk of breaking the window.

The problem of the window being broken can be solved by increasing the thickness of the dielectric window, but the microwave transmission property is deteriorated. This causes an increase in reflection wave, and therefore in some case, it becomes difficult to take matching. Further, if the thickness of the dielectric window is increased, the thermal stress created by plasma is further increased. Thus, as the area of the window is larger, a higher pressure-resistance is required.

An example of the method of avoiding the destruction of a window material by the stress is discussed in Japn. Pat. Appln. KOKAI Publication No. 2002-280196. A large-area surface wave plasma processing device of such a type that a plurality of rectangular-shaped waveguides are arranged in parallel at equal intervals is proposed in this document. In this plasma device, a plurality of microwave coupling pores are provided for each of the waveguides, and these coupling pores are each vacuum-sealed with a small dielectric window. In this manner, the difference in pressure between each waveguide and the processing chamber is maintained to be low. In other words, in place of using one window of a large area, a great number of windows of a small area are provided and thus the strength can be maintained even with a thin window material.

Further, Jpn. Pat. Appln. KOKAI Publication No. 11-026187 proposes a method of reducing a mechanical stress in the following manner. That is, another vacuum pump which is separate from the main vacuum pump provided in the processing chamber is installed in a waveguide connected to the microwave generator and thus the waveguide is evacuated to set the pressure to such that abnormal discharge does not occur inside the wave guide (>10 Torr(1.33×10³ Pa). In this manner, the difference from the pressure inside the processing chamber (several mTorr to several hundred mTorr (several Pa to several tens Pa)) is made small. In Jpn. Pat. Appln. KOKAI Publication No. 11-026187, an exhaust hole is formed in the end portion of the waveguide on the microwave input side, and through which the exhaustion is carried out. In this exhaustion system, the dielectric waveguide path jointed to the waveguide is used in the vacuum waveguide and electromagnetic wave radiating portion, and such a system is applied to a plasma processing device although it is not general.

### BRIEF SUMMARY OF THE INVENTION

As described above, a conventional plasma processing device for performing desired plasma processing by generating large-area, uniform and high-density plasma using microwave discharge of non-magnetic field entails the following drawback. That is, if the area of substrate to be processed is increased or a high-speed process is achieved, the risk of damaging the dielectric window due to the dynamic stress caused by the difference in the pressured applied to the dielectric window used for inputting microwave, and thermal stress created by plasma is increased.

As a solution to these problems, there have been several proposals such as the technique disclosed in the above-mentioned patent publication. However, the technique disclosed in Japn. Pat. Appln. KOKAI Publication No. 2002-280196 entails the following drawbacks. That is, since it is necessary to provide a sealing material for sealing vacuum for the number of coupling holes in this reference technique, the structure of the processing chamber becomes complicated, and the number of parts is increased, thereby making the cost of the device high. Further, in the case where a metal support plate is used to anchor a great number of small dielectric windows, plasma is localized in spots above these great number of dielectric windows since the surface wave generated is not propagated on the metal surface. As a result, plasma becomes ununiform in some cases especially when the atmosphere in the chamber is at a high pressure. For generating large-area plasma which is uniform over the entire area, such a structure that plasma is brought into contact uniformly with the entire surface of the dielectric body is a necessary condition.

On the other hand, the technique disclosed in Jpn. Pat. Appln. KOKAI Publication No. 11-026187 has the following features. That is, first, another vacuum pump which is separate from the main vacuum pump provided for the processing chamber is installed in the waveguide and thus the waveguide is evacuated by this vacuum pump, and secondly, the pressure is set to such that abnormal discharge does not occur inside the wave guide (1.33×10³ Pa or more at 1 kW). However, the separately provided vacuum pump is provided on the microwave input side, and thus this technique is applicable only in the special transmission and radiation method of microwave (or a device that utilizes a dielectric waveguide path). In other words, this technique is not applicable to the most popular method, which is the microwave discharge method that uses a slot antenna directly connected to a waveguide. Further, in connection with the second aspect described above, the pressure to prevent abnormal discharge is increased as the power of microwave is increased. Therefore, the pressure, at 10 kW, is 13.3×10³ Pa or more, which is close to the atmospheric pressure. It becomes impossible to decrease the thickness of the dielectric plate.

It should be noted that in the microwave discharge system using a slot antenna, the abnormal discharge occurs in micro space close to the slot antenna where the microwave electric filed is strongest.

As described above, any of the techniques that have been proposed so far in the prior art documents is not sufficiently satisfactory as a technique of resolving the dynamic stress and thermal stress applied to a dielectric window for microwave input, and thereby stably generating large-area and uniform high-density plasma.

Therefore, an object of the present invention is to provide a plasma processing device which can generate uniform and high-density large-area plasma while preventing abnormal discharge and reduce the dynamic stress and thermal stress applied to a dielectric window for microwave input, generated by the plasma, as well as a processing method using plasma.

According to an aspect of the present invention, there is provided a plasma-using processing device comprising: an electromagnetic wave generating source which generates an electromagnetic wave; a vacuum waveguide which propagates the electromagnetic wave generated from the electromagnetic wave generating source and input from an end, in a waveguide path a pressure of which is reduced to a vacuum state; and a processing chamber engaged air-tightly with the vacuum waveguide, which carries out processing using plasma generated by the electromagnetic wave radiated from the vacuum waveguide, characterized by further comprising:

an exhaust system which sets a pressure inside the vacuum waveguide lower than a pressure inside the processing chamber.

According to another aspect of the present invention, there is provided a plasma-using processing method carried out by a plasma-using processing device comprising: an electromagnetic wave generating source which generates an electromagnetic wave; a vacuum waveguide to which the electromagnetic wave generated from the electromagnetic wave generating source is input from an end, which is reduced to a vacuum state; and a processing chamber engaged air-tightly with the vacuum waveguide, the method characterized in that when processing a substrate to be processed loaded in the processing chamber, a pressure inside the vacuum waveguide is set lower than a pressure inside the processing chamber.

### BRIEF DESCRIPTION OF THE SEVERAL VIEWS OF THE DRAWING

FIG. 1 is diagram showing a conceptual cross sectional structure of a plasma processing device according to the first embodiment of the present invention.

FIG. 2A is diagram showing the structure of the plasma processing device of FIG. 1 when viewed from above in an oblique direction.

FIG. 2B is diagram showing a E plane and H plane of a vacuum waveguide.

FIG. 3 is diagram showing an example of arrangement of slots in a slot plate in the first embodiment.

FIG. 4 is diagram showing a conceptual structure of a plasma processing device according to the second embodiment of the present invention.

FIG. 5 is diagram showing an example of arrangement of slots in a slot plate in the second embodiment.

### DETAILED DESCRIPTION OF THE INVENTION

An embodiment of the present invention will now be described with reference to accompanying drawings.

This embodiment is a processing device which uses plasma, equipped with a processing chamber in which a waveguide is mounted and an inside of which is maintained at a predetermined degree of vacuum. The plasma processing device is based on such a technique that the difference in internal pressure between the processing chamber and the waveguide is reduced as compared to the difference from the atmospheric pressure, and thus the stress applied to the slot plate for inputting electromagnetic wave (to be referred to as microwave) and the dielectric window located between these is reduced. Further, this plasma processing device is a device that generates uniform and high density large-area surface wave plasma while preventing abnormal discharge generated in the processing chamber and/or the waveguide during a plasma generating period by maintaining the inside of each waveguide at a predetermined degree of vacuum.

It was found that the abnormal discharge in a microwave discharge system that uses a slot antenna (electromagnetic wave radiating portion: slot plate) of the plasma processing device occurs in the micro-space in the vicinity of the slot antenna where the microwave electric field is strongest. It was further found that in the above-described plasma-using processing device, there is a pressure at which discharge occurs most easily and at a pressure out of the discharge occurring pressure, discharge does not easily occur, or particularly, at a low pressure close to the vacuum, abnormal discharge substantially never occurs. In other words, in this embodiment, the inside of each waveguide is maintained at a low pressure, and thus the stress created by the pressure difference between the processing chamber and the waveguide is reduced, thereby preventing the abnormal discharge. In the following descriptions, the present embodiment will be referred to as vacuum waveguide in particular, since the waveguide of this embodiment is used in a vacuum state as compared to the conventional type used in the atmospheric pressure.

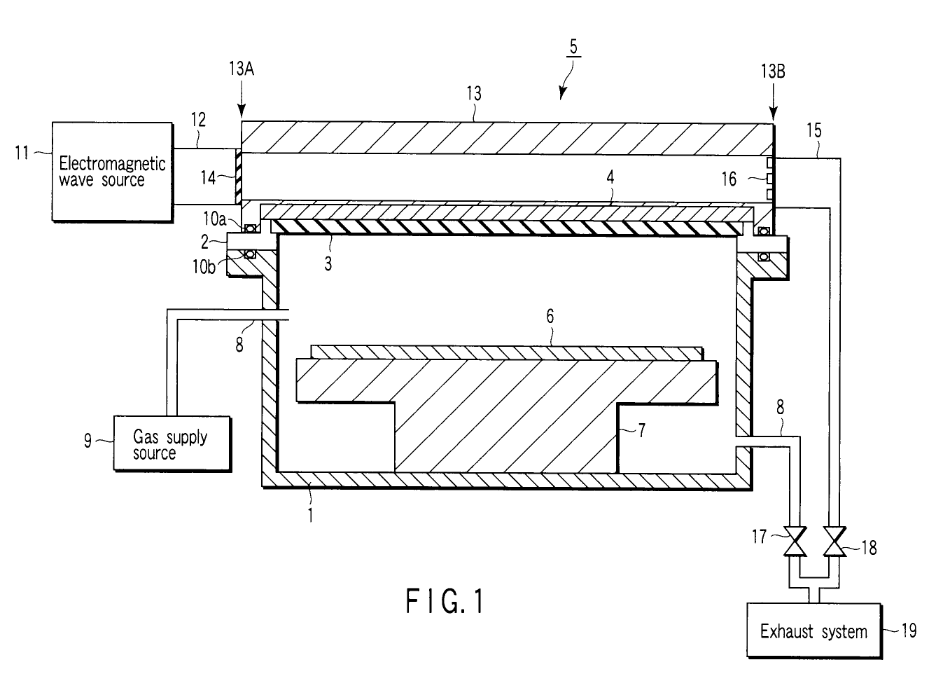

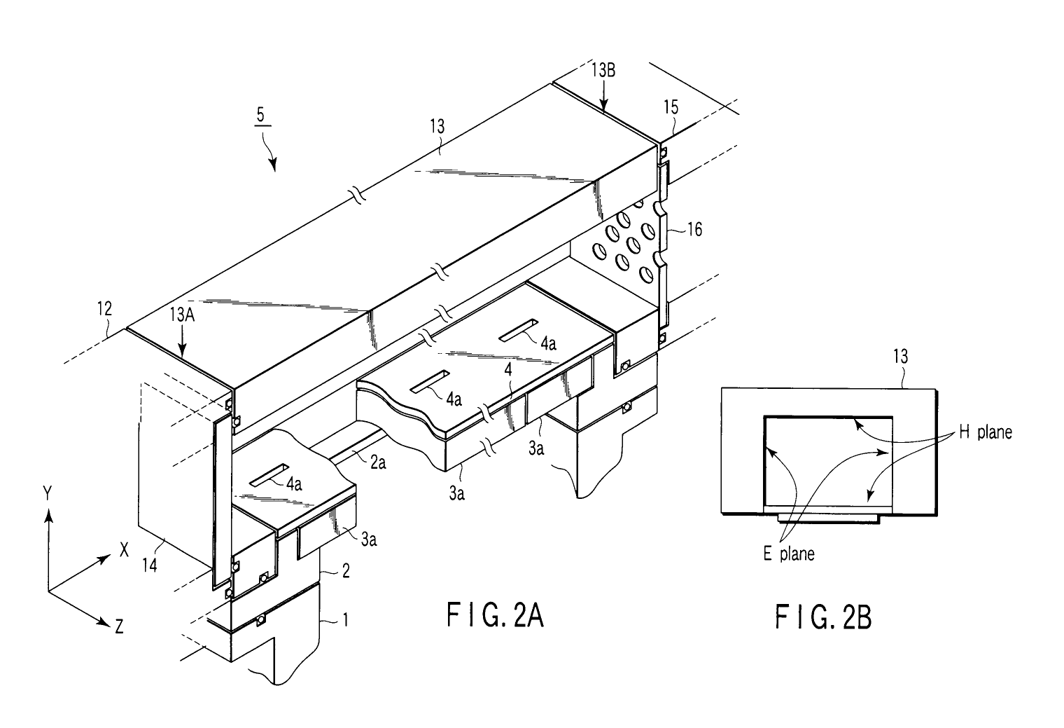

FIG. 1 illustrates a conceptual cross sectional structure of a plasma-using processing device according to the first embodiment taken in the longitudinal direction (microwave traveling direction) of the vacuum waveguide. FIG. 2A is diagram showing the structure of the plasma processing device of FIG. 1 when viewed from above in an oblique direction, and FIG. 2B is diagram showing a E plane and H plane of the vacuum waveguide.

This plasma processing device includes a processing chamber 1 in which a substrate stage 7 on which a substrate 6 to be processed, which can be mainly divided into a silicon substrate, or a glass substrate or the like, and a processing gas supply tube are provided, a ring-shaped spacer 2 provided air-tightly on an upper end portion of the processing chamber 1, a first dielectric member 3 fit into a notch made in an inner side of the spacer 2, and a microwave radiation system provided on the spacer 2 and radiating electromagnetic wave, for example, microwave to the processing chamber 1.

Next, the structures of their operations will now be described in concrete.

In an upper cover section of the processing chamber 1, a slot plate 4 which functions as an antenna (electromagnetic wave radiating portion) radiating microwave into the processing chamber is provided for a vacuum waveguide 13 in such a manner that it is brought into tight contact with the first dielectric member 3 when the device is assembled.

The processing chamber 1 is a cylindrical air-tight container having an opening in its upper surface, through which microwave is introduced, and it is made of a vacuum container material, or a metal material such as stainless steel or aluminum. In some cases, depending on the type of the device in which the processing chamber 1 is used (that is, for example, plasma CVD device or etching device), it is preferable that inner wall surfaces of the chamber should be treated by a film peel-off prevention treatment or anti-corrosion treatment. In the processing chamber 1, a substrate stage 7 is provided on which a substrate 6 to be processed, such as silicon wafer or glass plate, is placed. The substrate stage 7 has, for example, an electrostatic chuck function for adsorbing and holding the substrate 6 to be processed or a chuck function by vacuum suction (either of them shown in the figure), and heating/cooling function (not shown) of controlling the temperature of the to-be-processed substrate 6 at a desired temperature. Further, the substrate stage 7 is formed to be movable in a Z direction. The processing chamber 1 may be equipped with a conveying mechanism (not shown) or a load lock/unload lock mechanism (not shown) which is designed to load the to-be-processed substrate 6 onto the substrate stage 7 and unload it out of the chamber. Furthermore, the substrate stage 7 is connected to a power source (not shown), for example, a ground potential to be set to a potential corresponding to the processing.

In the meantime, a gas introduction port 8 through which a process gas, replacement gas or the like is introduced to the processing chamber 1 is provided in a side wall surface of the processing chamber 1. The port is connected to a gas supply source 9 via a gas introduction valve (not shown) such as a mass flow control valve, and thus a gas is introduced in accordance with necessity. In the gas supply source 9, a process gas source or plasma-generating gas source is provided in accordance with the type of the processing.

The gas introduction port 8 is arranged within the processing chamber 1 above the substrate stage 7 between the stage and the first dielectric member 3, and it is connected to a gas dispersion mechanism (not shown) which jets the process gas so as to make the gas concentration above the substrate 6 to be processed uniform. An example of the gas dispersion mechanism is a ring pipe which is provided in a ring shape above the outer circumference of the substrate 6 to be processed, and having a great number of gas jet pores directed to several sections of the to-be-processed substrate 6.

Alternatively, a gas shower head plate which generates surface wave plasma may be provided underneath the processing chamber 1 side of the first dielectric member 3. The gas shower head plate has, for example, a board shape provided underneath the processing chamber 1 side of the first dielectric member 3 and is made of the same material as that of the first dielectric member 3 so as to cover the entire surface of the dielectric member. The has shower head plate has a flow path formed therein and a great number of gas jet pores in one surface, which jet plasma-generating gas towards the entire surface of the substrate 6 to be processed. The gas shower head plate may be integrated to the first dielectric member 3. Further, it is possible to have such an internal path structure that an internal gas flow path is formed in the first dielectric member 3 throughout the inside of the first dielectric member 3 itself, and a great number of gas jet openings are made in a plurality of locations on the internal gas flow path. Besides these, there are various possible structures.

The surface wave plasma is generated underneath the processing chamber side 1 of the first dielectric member 3. The active spices from the surface wave plasma excites the process gas and thus the to-be-processed substrate 6 is processed.

A microwave radiation system 5 includes an electromagnetic wave source 11 which generates microwave (electromagnetic wave) of, for example, about 10 MHz to 25 MHz, a vacuum waveguide 13 formed into a hollow columnar shape having a rectangular cross section, which propagates the microwave to radiate in the processing chamber 1, a connection waveguide 12 which connects an irradiation opening of the electromagnetic wave source 11 and an end (on an introduction opening end 13A side) of the vacuum waveguide 13, a second dielectric member 14 inserted between the connection waveguide 12 and the introduction opening end 13A of the vacuum waveguide 13, which introduces the microwave and maintains the air-tightness in the vacuum waveguide 13 and a slot plate 4 which serves as an antenna (electromagnetic wave radiating portion) and radiates the microwave propagated into the processing chamber 1.

The slot plate 4 is fixated to the vacuum waveguide 13 at such a position where it is brought into tight contact with the first dielectric member 3 when the device is assembled. In the slot plate 4, slots 4a, which will be explained later, are formed such that they are dispersedly arranged. As they are arranged to correspond to the surface E (both side surfaces) and surface H (upper and lower surfaces) of the vacuum waveguide 13 when viewed from the X axis direction, the electromagnetic wave propagating through the vacuum waveguide 13 can be introduced to the processing chamber 1 at a high efficiency. In this embodiment, the shape of the vacuum waveguide 13 is not limited to rectangular, but it may be circular or ring.

Further, in the vacuum waveguide 13 of this embodiment, no member such as dielectric member is provided inside, where the microwave passes through. With this structure, there is no dielectric loss, and even when propagating an electromagnetic wave (microwave) of a high power, the electromagnetic wave can be propagated at a high efficiency. Therefore, it is useful for the formation of high-density plasma. The arrangement, opening area, the shape of the opening, etc. of the slots 4a can be adjusted as needed, and thus the microwave propagated in through the vacuum waveguide 13 can be radiated uniformly from each slot 4a into the processing chamber 1, thereby making it possible to generate a uniform surface wave on the first dielectric member 3. Thus, it is possible to generate plasma of a high uniformity within the plane.

Further, the vacuum waveguide 13 includes a waveguide exhaust port 15 provided to be air-tight at an opening end 13B opposing an introduction opening end 13A of the vacuum waveguide 13, and a waveguide terminal member 16 inserted between the opening end 13B and the waveguide exhaust port 15 and having a function of shielding microwave and transmitting gas.

To an end side of the vacuum waveguide 13, an exhaust system 19 is connected to the waveguide terminal member 16 and exhaust port 15. The waveguide terminal member 16 exhibits a reflection operation to, for example, the pressure resisting function and exhaust function which forms the vacuum waveguide 13, and the electromagnetic wave input. To the other end side of the vacuum waveguide 13, a connection waveguide 12 is connected via the first dielectric member 14.

The first dielectric member 14 has a function of transmitting electromagnetic wave propagated from the connection waveguide 12 at a high efficiency, and a pressure-resisting function which constitutes the vacuum waveguide 13, and it is sealed air-tightly to the other end of the vacuum waveguide 13. The exhaust system 19 exhausts the vacuum waveguide 13 such that the pressure inside the vacuum waveguide 13 is lower than the pressure inside of the processing chamber 1 when carrying out plasma processing. The exhaust system 19 exhausts the vacuum waveguide 13 such that the pressure inside the vacuum waveguide 13 is lower by order-of-magnitude than the pressure inside of the processing chamber 1. In order to prevent abnormal discharge, it is preferable that the exhaust system 19 exhausts the vacuum waveguide 13 such that the pressure inside the vacuum waveguide 13 is lower than the pressure inside of the processing chamber 1 and also than about 1.33×10⁻² Pa.

It is desired that the pressure sensor which measure the pressure inside the vacuum waveguide 13 should be installed in the vicinity of the second dielectric member 14. It is desired that the pressure sensor which measure the pressure inside the processing chamber 1 13 should be installed on an inner wall surface of the processing chamber 1 located between the substrate stage 7 and the slot plate 4. The exhaust system 19 monitors an output value of the pressure sensor provided in the processing chamber 1 and an output value of the pressure sensor provided in the vacuum waveguide 13, and exhaust them to control the pressure rate to a predetermined value. As the means for exhausting them to control the pressure rate to a predetermined value, it is possible that an exhaust vacuum pump in the vacuum waveguide 13 and an exhaust vacuum pump in the processing chamber are provided to be independent from each other. As other means for exhausting them to control the pressure rate to a predetermined value, it is possible that one pump or a common pump is used, and an appropriate pipe diameter ratio between the processing chamber exhaust port 8 and waveguide exhaust port 15 is selected.

As the waveguide terminal member 16, for example, a metal mesh screen or a metal plate with a great number of punch holes opened is applied. The waveguide terminal member 16 is made to have a function of shielding electromagnetic wave by, for example, reflection, and also it is formed to have exhaust pores to evacuate the vacuum waveguide 13, thus creating a function of vacuum sealing. In this manner, the device structure can be simplified. The diameter of the punch holes and the size of each mesh should be set smaller than the wavelength of the microwave used, and may be further adjusted as needed in accordance with the device structure, exhaust characteristics or the like. The size of the pores made in the waveguide terminal member 16, which is a conductor plate having a great number of openings within its entire surfaces, should be sufficiently smaller than the wavelength of the microwave. In other words, the size of the pores should be such that the terminal member serves as a sufficient shield, for example, reflection plate to the microwave, while being able to transmit the gas therethrough.

When the surface of the waveguide terminal member 16 is coated with a high-resistance material or a material with a large dielectric loss, the electromagnetic wave can be absorbed therein. In this case, the reflection wave is not created in the vacuum waveguide 13, and therefore the microwave can be propagated stably in the vacuum waveguide 13 even though the impedance changes due to variation in the state of plasma.

It is preferable that the microwave waveguide terminal member 16 should be made of a material having an anti-corrosion property against the process gas or the surface of the terminal member 16 should be subjected to anti-corrosive coating.

Further, the processing chamber 1 is connected to the exhaust system 19 from the exhaust port 25 for the processing chamber 1 through a valve 17, and the vacuum waveguide 13 is connected to the exhaust chamber 19 chamber from the exhaust port 15 for the vacuum waveguide 13 through a valve 18. The valves 17 and 18 are made of, for example, a gate valve and variable throttle valve, which can adjust the amount of exhaust (the amount of opening). The exhaust system 19, when used for a device such as CVD device, which involves a processing step in which some amount of process gas is allowed to flow in the processing chamber, should preferably be made of a vacuum pump, that is, an exhaust-type pump such as a turbo molecular pump. With this pump, the processing chamber 1 and vacuum waveguide 13 can be exhausted to a predetermined degree of vacuum by operating the valves as will be described later. It should be noted that in the case where the exhaust of the processing chamber 1 and the vacuum waveguide 13 is carried out by switching the turbo molecular pump and the valves, it is preferable that a primary coarse pump such as a dry pump should be used along with it. It is only natural that an independent exhaust system can be provided for each of the processing chamber 1 and the vacuum waveguide 13. Although it depends on the specification of the device, if the maximum value of the vacuum degree inside the vacuum waveguide 13 is set to about 10⁻³ Pa, the exhaust system can be realized only with a high-performance dry pump.

It should be noted that when a trap (not shown) cooled by liquid nitrogen or the like is provided in the waveguide exhaust port 15, it adsorbs the leaking process gas from the processing chamber 1, products or dusts, and thus the suction of these into the vacuum pump or attached of them to the turbo fan can be prevented.

In the exhaustion system 19, the microwave input to the vacuum waveguide 13 is reflected by the waveguide terminal member 16, and thus the exhaustion is carried out without having the microwave entering the exhaust pipe. In this manner, the inside of the vacuum waveguide 13 can be reduced in pressure to a desired degree of vacuum.

The spacer 2, mentioned above, is made of a metal material, and has a ring shape to fit to the upper surface ridge of the processing chamber 1. The spacer is interposed between the processing chamber 1 and the first dielectric member 3 when the first dielectric member 3 is mounted to fit therein. In this embodiment, O-rings 10a and 10b are set between the processing chamber 1 and the spacer 2 and between the spacer 2 and the vacuum waveguide 13, respectively, air-tightly to maintain the vacuum. For other locations, O-rings are used for pipe connection in the exhaust port and gas introduction port. The use of the O-rings here is on the assumption that the structural members are mounted and detached, and therefore a metal gasket may be used between structural members which are not attached and detached.

In this embodiment, the first dielectric member 3 and the second dielectric member 14 are made of a material which has properties that transmit the microwave but do not transmit the gas, and preferable examples of the material are quartz and alumina, and fluorine-based resin is applicable as well. When used, selection may be made from these materials as needed in accordance with the type of the substrate to be processed or processing step. It should be noted that the first dielectric member 3 shown in FIG. 1 is explained as one plate member; however when it is designed to enlarge the area of plasma generated, the opening area of the window (the opening section in the upper surface of the processing chamber 1) becomes larger, and therefore the area of the first dielectric member 3, which blocks the window, becomes large. Under these circumstances, when the member is one plate member, it is necessary to increase its thickness for its mechanical strength. Therefore, as shown in FIG. 2, it is possible to cut the member into first dielectric member segments each having an appropriate width, and to arrange them in line without intervals such that both ends of each segment are hooked on a guard portions 2a of the window frame of the spacer 2. The thickness of the first dielectric plate 3 should be made to such that the effect on the electromagnetic wave becomes as small as possible, which is for example, a thickness of λ/4 (here, λ represents the wavelength in the dielectric). Specifically, for the case of quartz, the thickness of the plate should preferably be about 10 mm. The width of the first dielectric plate 3 may be set appropriately in accordance with the opening area.

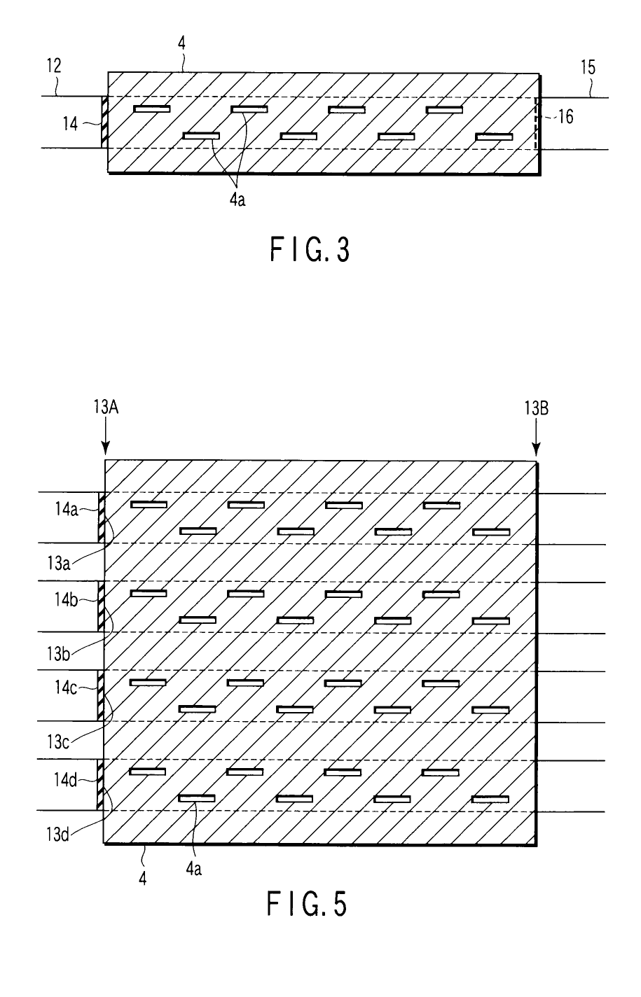

FIG. 3 shows an appearance of the structure of the slot plate 4 which serves as the electromagnetic wave radiating portion in this embodiment when viewed from above (from the vacuum waveguide 13 side).

This slot plate 4 is formed of a metal material into a plate shape, and a plurality of slots 4a, which are holes (through holes) to radiate the microwave propagated into the vacuum waveguide 13 to the processing chamber 1, are opened at even intervals over the entire surface of the slot plate. In this embodiment, the slots are made in two lines in a staggered manner as shown in FIG. 3. In this example, the shape of each slot 4a is rectangular, but naturally, the shape is not limited to this.

The slot plate 4 is fixed by screw (not shown) to the vacuum waveguide 13. With the arrangement of the first dielectric member 3 to cover the surface of the slot plate 4 on the processing chamber side, the microwave propagated within the vacuum waveguide can be introduced to the processing chamber at a high efficiency. Further, the electron density of plasma is increased higher than the cut-off density, the surface wave can be propagated on the surface of the first dielectric member 3, and thus it is possible to perform a plasma processing of an in-plane high uniformity by surface wave plasma.

The pressure reduction of the vacuum waveguide 13 and generation of surface wave plasma in the plasma processing device having the above-described structure will now be described.

First, the substrate 6 to be processed is loaded on the substrate stage 7 in the processing chamber 1 in this embodiment. The processing chamber 1 and the vacuum waveguide 13 of the microwave radiating system 5 are made air-tight, and then each of them is evacuated by the respective exhaust system. Thus, the inside of the processing chamber 1 is evacuated to a degree of vacuum based on the processing step, whereas the inside of the vacuum waveguide 13 is evacuated at least to about (1×10⁻⁴ Torr (1.33×10⁻² Pa) and maintained there. After that, the process gas for the processing step is introduced to the processing chamber 1 from the gas supply source and set an atmosphere at a predetermined degree of vacuum.

In this embodiment, it is preferable that the degree of vacuum in the processing chamber 1 in the atmosphere should be relatively close to the degree of vacuum in the vacuum waveguide 13 in order to reduce the stress onto the first dielectric member 3. For example, when the degree of vacuum in the processing chamber 1 during processing is several Torr (several hundred Pa), the degree of vacuum in the vacuum waveguide 13 is set to about 1.33×10⁻² Pa. After this atmosphere is set, the microwave is generated by the electromagnetic wave source 11 to be input to the vacuum waveguide 13. The input microwave is propagated in the vacuum waveguide 13, and then radiated into the processing chamber 1 from the slots 4a of the slot plate 4 serving as the antenna.

During this time, the microwave becomes surface wave on the entire surface of the first dielectric member 3, thereby generating plasma. This surface wave plasma makes it possible to carry out plasma processing at a large area and high uniformity within plane.

The exhaust system 19 of this embodiment evacuates the vacuum waveguide 13 by discharging the gas separated after shielding only the microwave through the waveguide exhaust port 15. When a member to shield the transmission of the microwave is provided at the end portion of the vacuum waveguide 13 and the exhaust system is connected to the exhaust port 15 jointed to this member, it is made independent from the processing chamber 13, and the conductance of the exhaustion is not deteriorated. It should be noted that as compared to that of Jpn. Pat. Appln. KOKAI Publication No. 11-026187 mentioned before, the structure of this embodiment is different therefrom in the following respect. That is, it is not a structure of exhaustion by providing an exhaust port which guides microwave on the microwave input side (introduction opening end 13A side) of the vacuum waveguide 13 as in Jpn. Pat. Appln. KOKAI Publication No. 11-026187, but in this embodiment, the gas in the vacuum waveguide 13 is evacuated through a mechanism that further shields the microwave from the area where the microwave is attenuated. Particularly, in Jpn. Pat. Appln. KOKAI Publication No. 11-026187, the pressure inside the waveguide is maintained higher than the pressure inside the processing chamber, for example, a high pressure of 1.33×10³ Pa so as to prevent abnormal discharge within the vacuum waveguide. By contrast, in this embodiment, the pressure inside the vacuum waveguide 13 is maintained lower than the pressure inside the processing chamber, for example, a pressure of 1.33×10⁻² Pa. In this respect as well, this embodiment is different from the reference document.

Therefore, with the plasma-using processing device of this embodiment, the pressure inside the vacuum waveguide 13 is set lower than the pressure inside the processing chamber during plasma processing, and thus it is possible to prevent abnormal discharge in the vacuum waveguide 13 and around the electromagnetic wave radiating member, where the electric field is strong. Further, since the pressure inside the vacuum waveguide 13 is maintained lower than the pressure inside the processing chamber, impurities do not enter from the vacuum waveguide 13 into the processing chamber even if the air-tightness between the vacuum waveguide 13 and the processing chamber is not sufficient.

Therefore, there is no problem if the air-tightness between the vacuum waveguide 13 and the processing chamber is low, and therefore in this embodiment, the maintenance of the air-tightness with sealing members such as O-rings and the like is simplified. It is only natural that if the air-tightness is maintained by providing sealing members, it is possible to carry out high-quality plasma processing. It should be noted that when the air-tightness is maintained by providing the sealing member between the vacuum waveguide 13 and the processing chamber 1, the slot plate 4 and the first dielectric member 3 are exposed to high heat due to the generation of the surface wave plasma. Therefore, in consideration of the case where plasma comes around between the waveguide 13 and the spacer 2, the air-tightness should be maintained with a member having a heat-resistance, such as metal gasket.

The effects of this embodiment having the above-described structure will now be described.
With the plasma processing device of this embodiment, a pressure of a high vacuum degree (at least about 1×10⁻⁴ Torr (1.33×10⁻² Pa)) is maintained in the vacuum waveguide 13, which is lower than the pressure inside the processing chamber during plasma process. Therefore, it is possible to prevent abnormal discharge in the vacuum waveguide 13 and around the electromagnetic wave radiating member, where the electric field is strong. Here, since the pressure inside the vacuum waveguide 13 is lower than the pressure inside the processing chamber 1 during plasma processing, impurities do not enter from the vacuum waveguide 13 into the processing chamber even if the sealing between the vacuum waveguide 13 and the processing chamber is not sufficient. Thus, with such a structure that the sealing portion between the vacuum waveguide 13 and the processing chamber 1 is simplified, it is still possible to carry out high-quality plasma.
With the plasma processing device of this embodiment, the air-tightness in the vacuum waveguide is maintained with the dielectric member provided in the microwave input side of the vacuum waveguide 13, and therefore the vacuum sealing region treated with a sealing member such as O-ring can be made small. Therefore, the simplification of the sealing structure is easily achieved.
Since this embodiment has such a structure that the waveguide terminal member 16 provided on the microwave reflection side of the terminal of the vacuum waveguide 13 reflects the microwave propagated and transmit the gas, there is no need to provide a separate exhaust port for vacuum exhaustion. Therefore, the exhaust structure is simplified and the conductance of the exhaustion is not deteriorated.
With the arrangement of the first dielectric member 14 to cover the surface of the slot plate 4, the microwave propagated can be introduced to the processing chamber 1 at a high efficiency. Further, the electron density of plasma is increased higher than the cut-off density, the surface wave can be propagated on the surface of the first dielectric member 14, and thus it is possible to perform plasma processing of an in-plane high uniformity by surface wave plasma.
Since no member is provided in the region where the microwave is propagated in the vacuum waveguide 13, the loss is very small. Even for a high power, the microwave can be propagated at a high efficiency, and therefore high-density plasma can be generated.
The position, size and shape of the slots 4a arranged in the slot plate 4 are adjusted so that the microwave propagated in the vacuum waveguide 13 is uniformly radiated from each slot 4a, and thus the microwave can be introduced to the processing chamber 1 to generate surface wave plasma having a high in-plane uniformity.
The plasma-using processing device of this embodiment can be applied to, for example, manufacturing processes for semiconductor elements such as thin film transistor (TFT) and metal oxide semiconductor element (MOS element), semiconductor devices such as semiconductor integrated circuit devices, and TFT circuits of display devices such as liquid crystal display devices.

Next, a plasma-using processing device according to the second embodiment of the present invention will now be described with reference to FIG. 5, which illustrates the conceptual structure of the device.

With regard to the structural parts of this embodiment, similar parts to those already discussed in the first embodiment will be designated by the same reference symbols, and the detailed explanations therefore will not be repeated.

The above-described first embodiment was explained in connection with an example in which a microwave radiating system including one electromagnetic wave source 11 and one vacuum waveguide 13 is mounted in the plasma processing device. In an actual occasion where a vacuum waveguide 13 which uses microwave is mounted in a plasma processing device, such a microwave radiating system including one electromagnetic wave source 11 and one vacuum waveguide 13 may be practical if the substrate to be processed has a relatively small area having a diameter of a silicon wafer (which is about 300 mm at maximum). However, if the substrate to be processed is for a liquid crystal device substrate of, for example, 45 inches (about 1 m) or more, used in displays for which there is a demand of increasing the display area, the processing chamber becomes large in size to deal with such a situation, and further the microwave radiating system must attend such a situation as well.

Under these circumstances, in the second embodiment, four electromagnetic wave sources 11a to 11d and four vacuum waveguides 13a to 13d, each of which has the same structure as that of the respective one of the first embodiment, are used and each of the wave sources and each respective one of waveguides are paired in such an arrangement to generate surface wave plasma which can carry out on the substrate to be processed a high in-plane uniformity plasma processing. In other words, four of the rectangular vacuum waveguides used in the first embodiment are arranged to generate surface wave plasma of substantially a square shape. In this embodiment, the plasma generating surface is shaped into substantially a square, but naturally, the shape is not limited to this. It should be shaped as needed in accordance with the shape of the substrate or processing chamber.

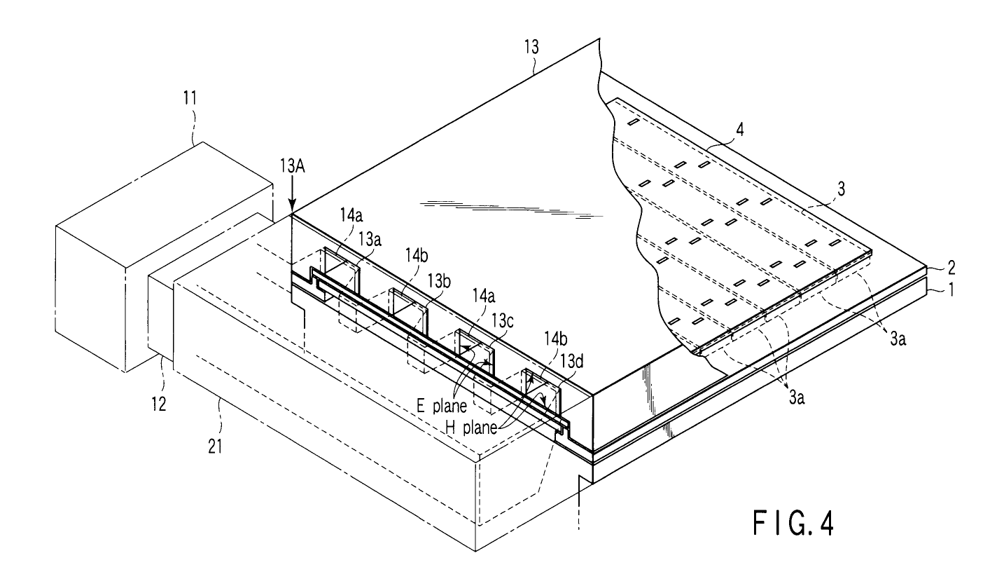

In this embodiment, the waveguides 13a to 13d are arranged in four lines to be parallel with each other as shown in FIG. 4. An output opening of a distribution waveguide 21 is air-tightly connected to the microwave input opening side (the introduction opening end 13A side) of each of the vacuum waveguides 13, and one electromagnetic wave source 11 is connected to the input opening side. Here, naturally, an electromagnetic wave source 11 may be provided for each of the vacuum waveguides 13a to 13d without using the distribution waveguide 21.

The distance between the vacuum waveguides 13a to 13d and the size of the slot plate 4 (the position of each slot) are set based on experience, simulation by computer, or the like. In this embodiment, the slots 4a are arranged as can be seen in FIG. 5, and they are the same as the slots 4a of the slot plate 4 of the first embodiment (shown in FIG. 3). The slots 4a are provided to correspond to E plane or H plane of the vacuum waveguides, respectively.

The exhaust system may be arbitrary as long as it is possible to obtain such exhaustion properties that the vacuum waveguides 13a to 13d have the same vacuum degree at the same time. Particularly, if the vacuum waveguides 13a to 13d have different degrees of vacuum during exhaustion, different stresses are generated respectively. Further, when they have great dispersion with respect to the vacuum degree of the processing chamber 1, the most stressed portion may be damaged. In order to avoid this, the exhaustion must be uniform.

Further, in the processing chamber 1 and the vacuum waveguides 13a to 13d as well, the exhaustion is carried out at the same time and to achieve similar degrees of vacuum. As the exhaust system 19, one vacuum pump is connected to the exhaust port 15 of each of the vacuum waveguides 13a to 13d via a valve. The vacuum pump for the processing chamber may be a separate one from the vacuum pump of each vacuum waveguide, or as in the case of the first embodiment described above, the exhaustion of the processing chamber 1 and each of the vacuum waveguides 13a to 13d can be carried out by one vacuum pump.

This embodiment having the structure described above includes a plurality of vacuum waveguides for microwave radiation and a plurality of slots 4a provided to correspond to a E plane or H plane of these vacuum waveguides. Therefore, the microwave propagated in the vacuum waveguides 13 can be introduced to the processing chamber 1 at a high efficiency.

In this embodiment, during surface wave plasma is generated in the processing chamber 1 to carry out processing, the pressure inside the vacuum waveguides 13 is maintained lower than the pressure inside the processing chamber 1, at a vacuum. Therefore, it is possible to prevent abnormal discharge in a broad discharge pressure range and a broad microwave input power range.

For example, under the conditions that the input of 2.45 GHz microwave is 6 kW per waveguide and the vacuum degree (process pressure) in the Argon atmosphere in the long-scale processing chamber 1 (L 1 m×W 0.3 m×H 0.3 m) is 100 mTorr (1.33 Pa), when the vacuum degree in the vacuum waveguides 13 is lower than the pressure in the processing chamber 1, that is, for example, a vacuum degree of 10⁻⁴ Torr (1.33×10⁻² Pa), it is possible to prevent abnormal discharge in the vacuum waveguides 13 where the electric field is strong, or caused by the electromagnetic wave source 11.

The degree of vacuum in the vacuum waveguides 13 should be lower than the pressure inside the processing chamber 1, and most preferably, 10⁻⁴ Torr or less.

Further, as in the case of the first embodiment, the pressure inside the processing chamber 1 during plasma processing is higher than 1 Pa. Therefore, when the degree of vacuum in the vacuum waveguides 13 is 1.33×10⁻² Pa or lower, and the vacuum sealing between the vacuum waveguides 13 and the processing chamber 1 is not sufficiently, gas may leak into the vacuum waveguides 13 but impurities do not enter the processing chamber 1 since the pressure in the processing chamber 1 is higher than the pressure in the vacuum waveguides 13. With this structure, it is possible to carry out a process with high-quality plasma with a structure in which the sealing member is simplified.

As described above, the effect of this embodiment is that in addition to the first effect discussed above, it is possible to provide a plasma-using processing device for a to-be-processed substrate having a large area, which can prevent abnormal discharge and generate a uniform high-density and large-area surface wave plasma by microwave discharge of non-magnetic field.

It should be noted that this plasma-using processing device can be easily mounted to a film forming device such as plasma CVD used in, for example, manufacture of semiconductor devices, display devices, or a heat processing device which carries out re-crystallization process or thermal reaction process (nitriding or oxidizing) or an etching device for dry etching, to obtain the above-described effect.

The above-discussed embodiments were explained in connection with an example of a processing device which utilizes a type of remote plasma, in which surface wave plasma is generated in the vicinity of the inner wall surface of the processing chamber 1 of the first dielectric member 3, and the process gas is excited by active particles generated by the surface wave plasma, thereby forming a film or performing etching. It is alternatively possible to process a substrate to be processed with plasma generated by exciting the process gas by electromagnetic wave input to the processing chamber 1.

As described above, according to the present invention, it is possible to provide a plasma processing device which can generate uniform high-density large-scale plasma while preventing abnormal discharge and also reduce the dynamic stress and thermal stress applied to a window of a dielectric member through which microwave generated by plasma is input, as well as such a plasma processing method.

What is claimed is:

1. A plasma-using processing device comprising:
an electromagnetic wave generating source which generates an electromagnetic wave;
a vacuum waveguide which propagates the electromagnetic wave generated from the electromagnetic wave generating source and input from an end, in a waveguide path a pressure of which is reduced to a vacuum state;
a processing chamber engaged air-tightly with the vacuum waveguide, which carries out processing using plasma generated by the electromagnetic wave radiated from the vacuum waveguide; and
an exhaust system which sets a pressure inside the vacuum waveguide lower than a pressure inside the processing chamber.

2. A plasma-using processing device comprising:
an electromagnetic wave generating source which generates an electromagnetic wave;
a vacuum waveguide which propagates the electromagnetic wave and is reduced to a vacuum state;
a processing chamber engaged air-tightly with the vacuum waveguide; and
an exhaust system which sets a pressure inside the vacuum waveguide lower than a pressure inside the processing chamber, and at least to a pressure lower than about 1.33×10⁻² Pa.

3. A plasma-using processing device comprising:
an electromagnetic wave generating source which generates an electromagnetic wave;
a plurality of vacuum waveguides each of which propagates the electromagnetic wave generated from the electromagnetic wave generating source and input from an end, in a waveguide path a pressure of which is reduced to a vacuum state;
a processing chamber engaged air-tightly with each of the vacuum waveguide, which carries out processing using plasma generated by the electromagnetic wave radiated from each of the vacuum waveguides; and
an exhaust system which sets a pressure inside each of the vacuum waveguides lower than a pressure inside the processing chamber, and to a same degree of vacuum.

4. The plasma-using processing device according to any one of claims 1 to 3, wherein the vacuum waveguide is provided with a dielectric partition wall which transmits the electromagnetic wave generated from the electromagnetic wave generating source and air-tightly seals the waveguide at one end on the electromagnetic wave generating source side, and a waveguide terminal member which shields the electromagnetic wave but transmits a gas at an other end.

5. The plasma-using processing device according to any one of claims 1 to 3, wherein a joint surface between the vacuum waveguide and the processing chamber is provided air-tightly with a dielectric member which transmits the electromagnetic wave propagated in the vacuum waveguide and can set the pressure in the vacuum waveguide lower than the pressure inside the processing chamber.

6. The plasma-using processing device according to claim 4, wherein the waveguide terminal member which shields the electromagnetic wave but transmits the gas has at lease one function of reflecting the electromagnetic wave and absorbing the electromagnetic wave, and has a pore opened therein having a pore diameter smaller than a wavelength of the electromagnetic wave.

7. The plasma-using processing device according to any one of claims 1 to 3, wherein the electromagnetic wave radiating member comprises a conductive material, and includes a slot plate having one or more slots opened therein which catches the electromagnetic wave propagated, and
the first dielectric member covers an entire surface of the slot plate on the processing chamber side, which is provided air-tightly to be integrated therewith, thereby generating surface wave plasma on a surface of the first dielectric member by the electromagnetic wave caught.

8. The plasma-using processing device according to claim 7, wherein the slot plate is provided to correspond to a E plane or H plane of the vacuum waveguide.

9. The plasma-using processing device according to any one of claims 1 to 3, wherein the vacuum waveguide is of a square, circular or a ring shape.

10. The plasma-using processing device according to any one of claims 1 to 3, wherein the pressure inside the vacuum waveguide is lower than a pressure at which abnormal discharge occurs in the vacuum waveguide due to a microwave power necessary for the processing.

11. The plasma-using processing device according to any one of claims 1 to 3, wherein the exhaust system is connected to one end side of the vacuum waveguide via a waveguide terminal member and a exhaust port.

12. The plasma-using processing device according to claim 11, wherein the waveguide terminal member exhibits a pressure-resisting function and an exhaust function by which the vacuum waveguide is constituted, and a reflection operation against the electromagnetic wave input thereto.

13. A plasma-using processing method carried out by a plasma-using processing device comprising: an electromagnetic wave generating source which generates an electromagnetic wave; a vacuum waveguide to which the electromagnetic wave generated from the electromagnetic wave generating source is input from an end, which is reduced to a vacuum state; and a processing chamber engaged air-tightly with the vacuum waveguide,
the method wherein when processing a substrate to be processed loaded in the processing chamber, a pressure inside the vacuum waveguide is set lower than a pressure inside the processing chamber.

14. A plasma-using processing method carried out by a plasma-using processing device comprising: an electromagnetic wave generating source which generates an electromagnetic wave; a vacuum waveguide which propagates the electromagnetic wave and is reduced to a vacuum state; and a processing chamber engaged air-tightly with the vacuum waveguide,
the method in that when processing a substrate to be processed loaded in the processing chamber, a pressure inside the vacuum waveguide is set lower than a pressure inside the processing chamber, and to at least a pressure lower than about 1.33×10⁻² Pa.

15. A plasma-using processing method according to claim 10, wherein a pressure inside the vacuum waveguide is controlled such that an output value of a pressure sensor which measures the pressure inside the vacuum waveguide and an output value of a pressure sensor which measures the pressure inside the processing chamber are at a predetermined pressure ratio.
